(19) United States
(12) Patent Application Publication
(10) Pub. No.: US 2012/0161768 A1
(43) Pub. Date: Jun. 28, 2012

(54) SYSTEM AND METHOD FOR COMMUNICATING DATA

(75) Inventors: Christopher Judson Hardy, Schenectady, NY (US); Thomas Kwok-Fah Foo, Clifton Park, NY (US); Robert Steven Stormont, Hartland, WI (US); Kenneth William Rohling, Porter Corners, NY (US); Selaka Bandara Bulumulla, Niskayuna, NY (US)

(73) Assignee: GENERAL ELECTRIC COMPANY, SCHENECTADY, NY (US)

(21) Appl. No.: 12/977,551

(22) Filed: Dec. 23, 2010

(51) Int. Cl. G01R 33/44

(52) U.S. Cl. 324/318

(57) ABSTRACT

A system for communicating data in a magnetic resonance imaging system in one embodiment includes a first array of receiver coils disposed on a first flexible substrate having at least one edge, wherein the flexible substrate is configured to be disposed upon or under a section of a patient under exam, wherein the first array of receiver coils is configured to acquire imaging data from the patient positioned on a patient support in the imaging system. Additionally, the system includes at least one blanket connector disposed along the at least one edge of the first flexible substrate, wherein the at least one blanket connector is electrically coupled to the first array of receiver coils in the first flexible substrate. Moreover, the system includes at least one system connector disposed proximate the patient support and configured to communicate with the imaging system, wherein the at least one blanket connector is configured to be detachably coupled to the at least one system connector, and wherein the first array of receiver coils is configured to communicate the acquired imaging data to the imaging system. In one embodiment the electrical connector is further configured to physically secure the first array of receiver coils in place and prevent the first array of receiver coils from moving.

### BACKGROUND

Embodiments of the present disclosure relate to communication of signals in signals, and more particularly to the communication of signals in a magnetic resonance (MR) imaging system.

In just a few decades, the use of magnetic resonance imaging (MRI) scanners has grown tremendously. MRI scans are being increasingly used to aid in the diagnosis of multiple sclerosis, brain tumors, torn ligaments, tendonitis, cancer, strokes, and the like. As will be appreciated, MRI is a noninvasive medical test that aids physicians in the diagnoses and treatment of various medical conditions. The enhanced contrast that an MRI scan provides between the different soft tissues of the body allows physicians to better evaluate the various parts of the body and determine the presence of certain diseases that may not be assessed adequately with other imaging methods such as X-ray, ultrasound, or computed tomography (CT).

An MRI system typically includes one or more coils to generate the magnetic field. Additionally, the MRI system also includes one or more MRI receiver coils configured to detect signals from a gyromagnetic material within a patient. These MRI receiver coil arrays typically entail the use of bulky cables. Use of these bulky cables increases the difficulty in situating the receiver coils over the patient before the scanning procedure. Furthermore, the advent of parallel imaging has led to an increase in the number of MRI receiver channels. Unfortunately, this increase in the number of receiver channels has further exacerbated the problem with a corresponding increase in the number of bulky cables.

Moreover, MRI receiver arrays are often positioned over the patient and secured in place by means of straps or blankets which are fastened (sometimes with hook and loop fasteners, such as VELCRO) at either side of the patient cradle and are pulled tight to insure that the receiver array does not move or slip out of position during the exam. The steps of positioning the receiver arrays, securing them in place, connecting the cables, and positioning the cables to minimize patient discomfort in the patient setup before scanning unfortunately lengthen exam times and decrease patient comfort.

It would therefore be desirable to develop a lightweight array of receiver coils that can be easily positioned and secured on the patient in order to circumvent associated problems, such as weight and complexities of cables.

### BRIEF DESCRIPTION

In accordance with aspects of the present technique, a system for communicating data in a magnetic resonance imaging system. The system includes a first array of receiver coils disposed on a first flexible substrate having at least one edge, wherein the flexible substrate is configured to be disposed upon or under a section of a patient under exam, wherein the first array of receiver coils is configured to acquire imaging data from the patient positioned on a patient support in the imaging system. Additionally, the system includes at least one blanket connector disposed along the at least one edge of the first flexible substrate, wherein the at least one blanket connector is electrically coupled to the first array of receiver coils in the first flexible substrate. Moreover, the system includes at least one system connector disposed proximate the patient support and configured to communicate with the imaging system, wherein the at least one blanket connector is configured to be detachably coupled to the at least one system connector, and wherein the first array of receiver coils is configured to communicate the acquired imaging data to the imaging system. In one embodiment the electrical connector is further configured to physically secure the first array of receiver coils in place and prevent the first array of receiver coils from moving.

In accordance with another aspect of the present technique, a system for communicating data in a magnetic resonance imaging system is presented. The system includes a first flexible substrate having at least one edge and configured to be disposed on or under a patient, wherein the first flexible substrate comprises a first array of receiver coils configured to acquire data from the patient positioned on a patient support in the imaging system. Moreover, the system includes a first blanket connector disposed along the at least one edge of the first flexible substrate, wherein the at least one blanket connector is electrically coupled to the coils in the first array of receiver coils, and wherein the at least one blanket connector is configured to be detachably coupled to one or more sides of the patient support. In addition, the system includes a second flexible substrate having at least one edge and configured to be disposed on or under a patient. The system also includes a second blanket connector disposed along the at least one edge of the second flexible substrate, wherein the second blanket connector is configured to be detachably coupled to one or more sides of the patient support.

In accordance with yet another aspect of the present technique, a method for communicating signals in a magnetic resonance imaging system is presented. The method includes disposing an array of receiver coils on one or more sections of a flexible substrate, wherein the array of receiver coils is configured to acquire data from a patient positioned on a patient support in the imaging system. Furthermore, the method includes disposing one or more sections of the flexible substrate about the patient. In addition, the method in one example includes communicating patient data acquired by the array of receiver coils to processing circuitry in the magnetic resonance imaging system through at least one blanket connector that is electrically coupled to the array of receiver coils.

In accordance with another aspect of the present technique, a system magnetic resonance imaging system is presented. The system includes an acquisition subsystem configured to acquire image data, wherein the acquisition subsystem includes a subsystem for communicating data in the imaging system, the subsystem including an array of receiver coils disposed on a first flexible substrate having at least one edge, wherein the flexible substrate is configured to be disposed upon or under a section of a patient under exam, wherein the first array of receiver coils is configured to acquire imaging data from the patient positioned on a patient support in the imaging system, at least one blanket connector disposed along the at least one edge of the first flexible substrate, wherein the at least one blanket connector is electrically coupled to the first array of receiver coils in the first flexible substrate, and at least one system connector disposed proximate the patient support and configured to communicate with the imaging system, wherein the at least one blanket connector is configured to be detachably coupled to the at least one system connector, and wherein the first array of receiver coils is configured to communicate the acquired imaging data to the imaging system. The system also includes a processing subsystem in operative association with the acquisition subsystem and configured to process the acquired image data.

### DRAWINGS

These and other features, aspects, and advantages of the present invention will become better understood when the following detailed description is read with reference to the accompanying drawings in which like characters represent like parts throughout the drawings, wherein:

FIG. 1 is a block diagram illustration of an exemplary imaging system in the form of a magnetic resonance imaging (MRI) system configured to use the systems and methods of FIGS. 2-4;

FIG. 2 is a diagrammatic illustration of one embodiment of a system for communicating data in the imaging system of FIG. 1, in accordance with aspects of the present technique;

FIG. 3 is a diagrammatic illustration of another embodiment of the system for communicating data of FIG. 2, in accordance with aspects of the present technique;

FIG. 4 is a diagrammatic illustration of yet another embodiment of the system for communicating data of FIG. 2, in accordance with aspects of the present technique; and

FIG. 5 is a flow chart depicting an exemplary method for communicating data using the systems of FIGS. 2 and 3, in accordance with aspects of the present technique.

### DETAILED DESCRIPTION

As will be described in detail hereinafter, a method for communicating data and various embodiments of systems for communicating data are presented. By employing the method and systems for communicating data described hereinafter, system size and complexity may be minimized, while enhancing the performance of the system.

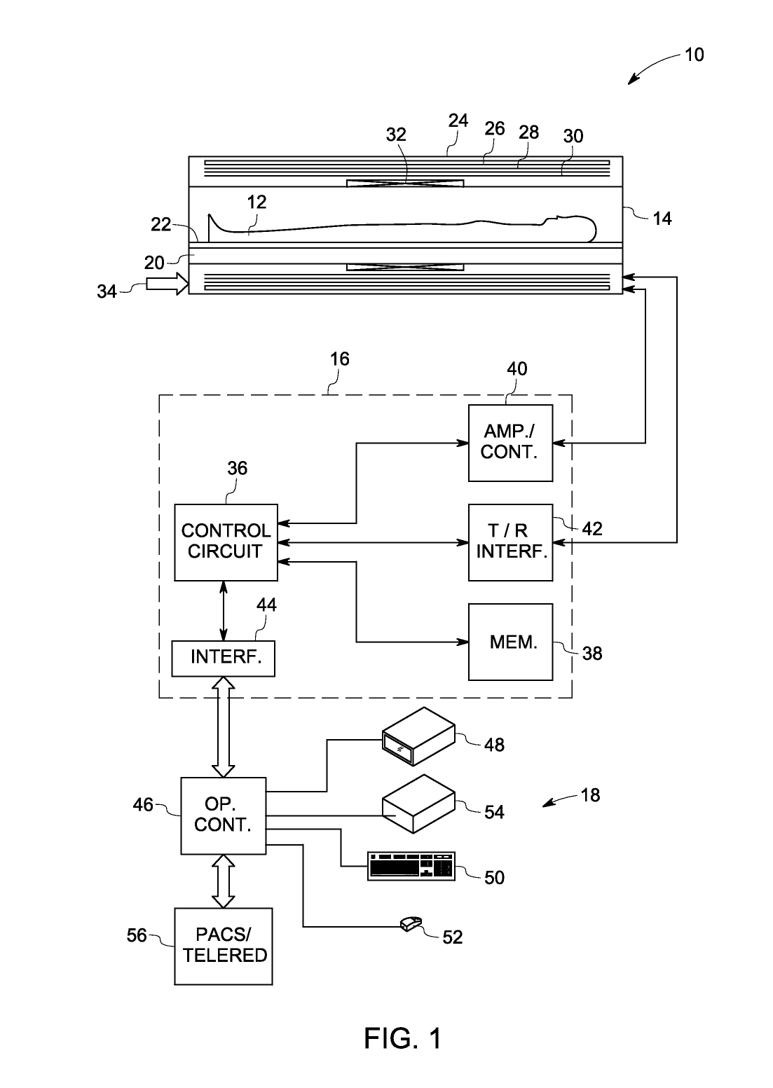

Turning now to the drawings, and referring to FIG. 1, a block diagram of an embodiment of an MRI imaging system 10 is depicted. The MRI system 10 is illustrated diagrammatically as including a scanner 14, scanner control circuitry 16, and system control circuitry 18. While the MRI system 10 may include any suitable MRI scanner or detector, in the illustrated embodiment the system includes a full body scanner including a patient bore 20 into which a cradle 22 may be positioned to place a patient 12 in a desired position for scanning. The scanner 14 may be of any suitable field strength, including scanners varying from 0.5 Tesla to 3 Tesla field strength and beyond. As used herein, the term patient is used to refer to a human person or animal that is the subject of the imaging application.

Additionally, the scanner 14 may include a series of associated coils for producing controlled magnetic fields, for generating radio-frequency (RF) excitation pulses, and for detecting emissions from gyromagnetic material within the patient 12 in response to such pulses. In the diagrammatical view of FIG. 1, a primary magnet coil 24 may be provided for generating a primary magnetic field generally aligned with patient bore 20. A series of gradient coils 26, 28 and 30 may be grouped in a coil assembly for generating controlled magnetic gradient fields during examination sequences as will be described in greater detail hereinafter. A RF coil 32 may be provided for generating radio frequency pulses for exciting the gyromagnetic material. In the embodiment illustrated in FIG. 1, the coil 32 also serves as a receiving coil. Thus, the RF coil 32 may be coupled with driving and receiving circuitry in passive and active modes for receiving emissions from the gyromagnetic material and for applying RF excitation pulses, respectively. Alternatively, various configurations of receiving coils may be provided separate from the RF coil 32. Such coils may include structures specifically adapted for target anatomies, such as head coil assemblies, and so forth. Moreover, receiving coils may be provided in any suitable physical configuration, including phased array coils, and so forth.

In a presently contemplated configuration, the gradient coils 26, 28 and 30 may have different physical configurations adapted to their function in the imaging system 10. As will be appreciated by those skilled in the art, the coils include conductive wires, bars or plates that are wound or cut to form a coil structure that generates a gradient field upon application of control pulses as described below. The placement of the coils within the gradient coil assembly may be done in several different orders. In one embodiment, a Z-axis coil may be positioned at an innermost location, and may be formed generally as a solenoid-like structure that has relatively little impact on the RF magnetic field. Thus, in the illustrated embodiment, the gradient coil 30 is the Z-axis solenoid coil, while coils 26 and 28 are Y-axis and X-axis coils respectively.

The coils of the scanner 14 may be controlled by external circuitry to generate desired fields and pulses, and to read signals from the gyromagnetic material in a controlled manner. As will be appreciated by those skilled in the art, when the material, typically bound in tissues of the patient 12, is subjected to the primary field, individual magnetic moments of the paramagnetic nuclei in the tissue partially align with the field. While a net magnetic moment is produced in the direction of the polarizing field, the randomly oriented components of the moment in a perpendicular plane generally cancel one another. During an examination sequence, an RF frequency pulse is generated at or near the Larmor frequency of the material of interest, resulting in rotation of the net aligned moment to produce a net transverse magnetic moment. This transverse magnetic moment precesses around the main magnetic field direction, emitting RF signals that are detected by the scanner 14 and processed for reconstruction of the desired image.

The gradient coils 26, 28 and 30 may be configured to serve to generate precisely controlled magnetic fields, the strength of which vary over a predefined field of view, typically with positive and negative polarity. When each coil is energized with known electric current, the resulting magnetic field gradient is superimposed over the primary field and produces a desirably linear variation in the Z-axis component of the magnetic field strength across the field of view. The field varies linearly in one direction, but is homogenous in the other two. The three coils have mutually orthogonal axes for the direction of their variation, enabling a linear field gradient to be imposed in an arbitrary direction with an appropriate combination of the three gradient coils.

The pulsed gradient fields perform various functions integral to the imaging process. Some of these functions are slice selection, frequency encoding and phase encoding. These functions may be applied along the X-axis, Y-axis and Z-axis of the original coordinate system or along other axes determined by combinations of pulsed currents applied to the individual field coils.

The slice select gradient determines a slab of tissue or anatomy to be imaged in the patient 12. The slice select gradient field may be applied simultaneously with a frequency selective RF pulse to excite a known volume of spins within a desired slice that precess at the same frequency. The slice thickness is determined by the bandwidth of the RF pulse and the gradient strength across the field of view.

The frequency encoding gradient is also known as the readout gradient, and is usually applied in a direction perpendicular to the slice select gradient. In general, the frequency encoding gradient is applied before and during the formation of the magnetic resonance (MR) echo signal resulting from the RF excitation. Spins of the gyromagnetic material under the influence of this gradient are frequency encoded according to their spatial position along the gradient field. By Fourier transformation, acquired signals may be analyzed to identify their location in the selected slice by virtue of the frequency encoding.

Finally, the phase encode gradient is generally applied before the readout gradient and after the slice select gradient. Localization of spins in the gyromagnetic material in the phase encode direction may be accomplished by sequentially inducing variations in phase of the precessing protons of the material using slightly different gradient amplitudes that are sequentially applied during the data acquisition sequence. The phase encode gradient permits phase differences to be created among the spins of the material in accordance with their position in the phase encode direction.

As will be appreciated by those skilled in the art, a great number of variations may be devised for pulse sequences employing the exemplary gradient pulse functions described hereinabove as well as other gradient pulse functions not explicitly described here. Moreover, adaptations in the pulse sequences may be made to appropriately orient both the selected slice and the frequency and phase encoding to excite the desired material and to acquire resulting MR signals for processing.

The coils of the scanner 14 are controlled by scanner control circuitry 16 to generate the desired magnetic field and RF pulses. In the diagrammatical view of FIG. 1, the scanner control circuitry 16 thus includes a control circuit 36 for commanding the pulse sequences employed during the examinations, and for processing received signals. The control circuit 36 may include any suitable programmable logic device, such as a CPU or digital signal processor of a general purpose or application-specific computer. Also, the control circuit 36 may further include memory circuitry 38, such as volatile and non-volatile memory devices for storing physical and logical axis configuration parameters, examination pulse sequence descriptions, acquired image data, programming routines, and so forth, used during the examination sequences implemented by the scanner.

Interface between the control circuit 36 and the coils of the scanner 14 is managed by amplification and control circuitry 40 and by transmission and receive interface circuitry 42. The amplification and control circuitry 40 includes amplifiers for each gradient field coil to supply drive current to the field coils in response to control signals from the control circuit 36. Transmit/receive (T/R) circuitry 42 includes additional amplification circuitry for driving the RF coil 32. Moreover, where the RF coil 32 serves both to emit the RF excitation pulses and to receive MR signals, the T/R circuitry 42 may typically include a switching device for toggling the RF coil between active or transmitting mode, and passive or receiving mode. A power supply, denoted generally by reference numeral 34 in FIG. 1, is provided for energizing the primary magnet 24. Finally, the scanner control circuitry 16 may include interface components 44 for exchanging configuration and image data with the system control circuitry 18. It should be noted that, while in the present description reference is made to a horizontal cylindrical bore imaging system employing a superconducting primary field magnet assembly, the present technique may be applied to various other configurations, such as scanners employing vertical fields generated by superconducting magnets, permanent magnets, electromagnets or combinations of these means.

The system control circuitry 18 may include a wide range of devices for facilitating interface between an operator or radiologist and the scanner 14 via the scanner control circuitry 16. In the illustrated embodiment, for example, an operator controller 46 is provided in the form of a computer workstation employing a general purpose or application-specific computer. The workstation also typically includes memory circuitry for storing examination pulse sequence descriptions, examination protocols, user and patient data, image data, both raw and processed, and so forth. Further, the workstation may further include various interface and peripheral drivers for receiving and exchanging data with local and remote devices. In the illustrated embodiment, such devices include a conventional computer keyboard 50 and an alternative input device such as a mouse 52. A printer 54 may be provided for generating hard copy output of documents and images reconstructed from the acquired data. Moreover, a computer monitor 48 may be provided for facilitating operator interface. In addition, the system 10 may include various local and remote image access and examination control devices, represented generally by reference numeral 56 in FIG. 1. Such devices may include picture archiving and communication systems, teleradiology systems, and the like.

As previously noted, MRI receiver coil arrays typically entail use of bulky cables that make it more difficult to position the MRI receiver coil arrays on a patient before initiating a scanning procedure. In accordance with aspects of the present application, an exemplary system 60 for acquiring data from a patient, for example, and communicating the acquired data to processing circuitry in the imaging system 10 (see FIG. 1) that circumvents the shortcomings of the presently available techniques is presented.

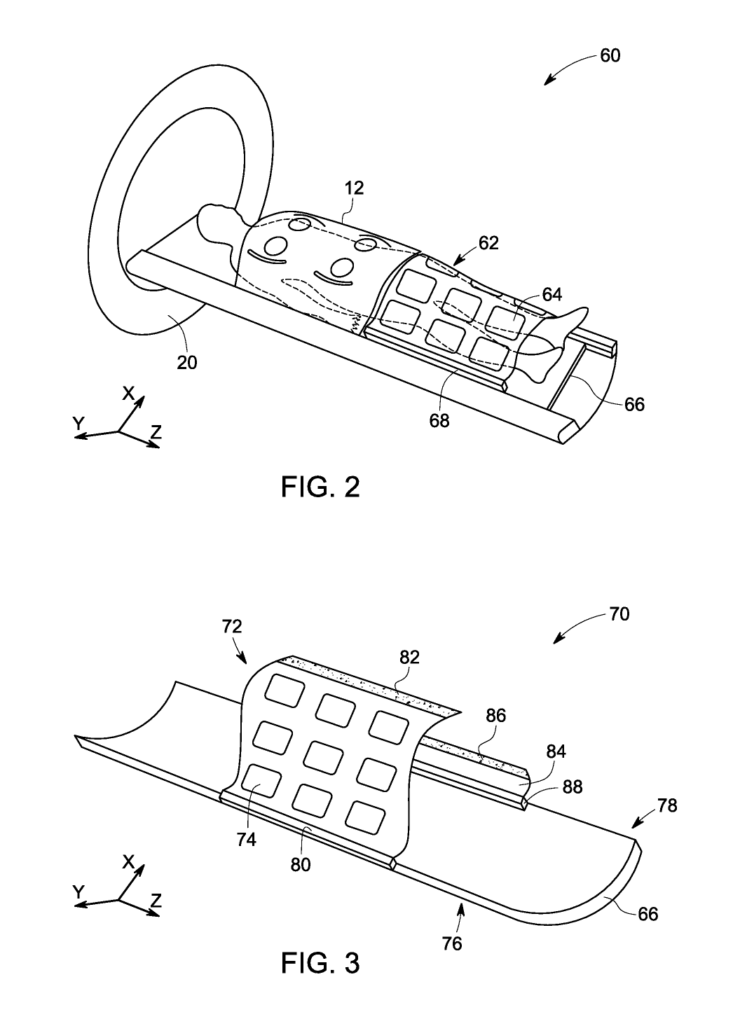

In accordance with further aspects of the present technique, a diagrammatic illustration of one embodiment 60 of a system for communicating data is presented in FIG. 2. The system 60 includes, for example, an arrangement of radio frequency (RF) receiver coils 64 on a flexible substrate 62. The flexible substrate 62 may be formed using a thin dielectric material such as a polyimide film or FR-4. Furthermore, the flexible substrate 62 may also incorporate a thin foam padding and/or covering, in certain embodiments. In accordance with other aspects of the present technique, the receiver coils 64 are integrated into certain forms of wearable clothing such as a vest or garment that is worn or otherwise draped around a patient in advance of the medical imaging procedure.

Furthermore, in accordance with certain other aspects of the present technique, the flexible substrate 62 is fashioned in the form of a blanket of coils. As used herein, the term blanket is used to broadly define a flexible substrate that can be worn or placed upon a patient 12. Accordingly, the blanket 62 includes an arrangement of one or more coils 64. Also, the blanket 62 is configured to be disposed on the patient 12 to cover the section of the patient that is the focus of the examination. As previously noted, the blanket can also be an article of clothing such as a vest, pants, skirt, robe or similar items that include the coils 64. This article of clothing can be placed onto the patient 12, particularly in advance of the imaging or scanning procedure. Moreover, prior to the commencement of the scanning procedure, the patient 12 is positioned on a patient cradle 66 of the imaging system 10. The terms patient support and patient cradle may be used interchangeably. It may be noted that although the embodiment of FIG. 2 depicts the blanket 62 as being draped over the patient 12, in certain other embodiments, the blanket 64 may also be disposed under the patient 12, for example. Alternatively, the blanket 62 may be disposed both over and under the patient 12.

Also, the size of the blanket 62 may be dependent upon an anatomical region of the patient 12 being scanned. Particularly, the blanket 62 may be sized such that the anatomical region of the patient 12 being scanned is adequately accommodated by the blanket 62. By way of example, if it is desirable to scan an upper region of the patient 12, then the blanket 62 may be patterned and sized to be wrapped around the upper portion of the patient 12 or be disposed under the upper portion of the patient 12. Similarly, if a lower region of the patient 12 is being scanned, then the blanket 62 may be patterned and sized to be wrapped around the lower portion of the patient 12 or be disposed under the lower portion of the patient 12.

Additionally, in accordance with aspects of the present technique, the blanket 62 may be fashioned to have a wide variety of shapes. For example, the blanket 62 may have a circular shape, a square shape, a rectangular shape, a triangular shape, a polygonal shape, or combinations thereof. Moreover, in this embodiment of the blanket 62, an “edge” of the blanket refers to any portion proximate the perimeter of the blanket 62. The blanket 62, in another embodiment, may be fashioned in the form of an article of clothing having the functional shape such as a vest, pants, skirt, or robe to be worn by the patient during the scanning procedure. For the blanket embodiment that is an article of clothing, the “edge” of the blanket refers to any of the perimeters of the clothing. Moreover, in accordance with further aspects of the present technique, more than one blanket may be disposed upon the patient 12 for the imaging applications.

The blanket 62 is configured to have at least one blanket connector 68 in order to communicate with the imaging system 10 and allow for the imaging data from the coils 64 to be properly conditioned and processed by the imaging system 10. In one embodiment, the blanket connector 68 is disposed along an “edge” of the blanket, wherein the edge refers to any portion proximate the perimeter of the blanket. For example, in the embodiment depicted in FIG. 2, the blanket of coils 62 has a first edge and a second edge. Furthermore, one or more blanket connectors may be disposed along the first edge or the second edge or both the first edge and the second edge of the blanket of coils 62. Reference numeral 68 is generally representative of a blanket connector that provides for the communication between the blanket 62 and the imaging system 10. In the depicted embodiment, the blanket connector 68 is disposed along an edge of the blanket of coils 62. The blanket connector 68 is operationally coupled to the coils 64 in the blanket 62 through internal cabling (not shown in FIG. 2). The internal cabling may be in the form of various electrical wiring such as micro-coax, micro-strip transmission lines or strip-line transmission lines. Furthermore, the transmission lines may be patterned directly on or within the flexible substrate to maintain the overall flexibility.

In another embodiment, the blanket connector may be positioned within any portion of the face of the blanket 62 and not limited to the edge of the blanket. However, this embodiment may entail attaching a cable harness to the blanket connector, where the blanket connector is disposed on top of or under the blanket. It is also noted that there can be more than one blanket connector that can be disposed on one or more edge sections as well as from the face and edges of the blanket 62.

Moreover, the blanket connector 68 is configured to support the communication of RF signals as well as DC signals. Hence, the characteristic impedance of signal paths through the blanket connector 68 is matched to the characteristic impedance of cables that constitutes internal cabling.

Furthermore, in accordance with aspects of the present technique, the blanket connector 68 is detachably coupled to one or more sides of the patient cradle 66. Particularly, in one example, at least one system connector may be disposed proximate the patient cradle 66, where the system connector is configured to communicate with the imaging system 10. Additionally, the system connector is configured to be mateably and/or detachably coupled to the blanket connector 68. Accordingly, the blanket connector 68 aids in electrically coupling the coils 64 in the blanket 62 to cables (not shown in FIG. 2) in the patient cradle 66 via the system connector. The cables in the patient cradle 66 are in turn coupled to receivers (not shown in FIG. 2) in the imaging system 10. It may be noted that in certain embodiments, preamplifiers (not shown in FIG. 2) may be located either directly on the coils 64 in the blanket 62 or in the patient cradle 66. In one embodiment, when the preamplifiers are placed in the patient cradle 66, the electrical length of connection from the coil 64 to the preamplifier is maintained at an integral multiple of one-half a wavelength, as will be appreciated by those skilled in the art. The preamplifiers are configured to amplify data signals acquired by the coils 64. Small-footprint, planar baluns may also be attached to each coil 64, or between the coil and internal cabling.

As noted hereinabove, the blanket connector 68 electrically couples the coils 64 in the blanket 62 to cables in the patient cradle 66. Additionally, the blanket connector 68 can also be configured to aid in physically securing the blanket 62 to the patient cradle 66 in order to minimize movement of the blanket 62. Hence, the blanket connector 68 combines the functions of electrically coupling the coils 64 to cabling in the patient cradle 66 and physically securing the blanket 62.

In accordance with further aspects of the present technique, the blanket of coils 62 is configured to accommodate an array of patient sizes. Accordingly, the blanket is configured to be expandable or otherwise positionable to accommodate an array of patient sizes and imaging applications. Turning now to FIG. 3, another embodiment 70 of the system 60 of FIG. 2 for communicating data is presented. In the system 70 depicted in FIG. 3, the system 70 includes a flexible substrate patterned as a blanket having a plurality of coils disposed thereon. Particularly, the blanket has a first section 72 and a second section 84. Reference numeral 74 is generally representative of coils in the first section 72 of the blanket of coils. As depicted in FIG. 3, the first section 72 of the blanket of coils is operationally coupled to a first side 76 of the patient cradle 66. In one embodiment, a blanket connector 80 is employed to couple a first edge of the first section 72 of the blanket to the first side 76 of the patient cradle 66. As previously described, at least one system connector may be disposed proximate the patient cradle 66, where the system connector is configured to be mateably and/or detachably coupled to the blanket connector 80 and also communicate with the imaging system 10. Furthermore, in certain embodiments, a fastener 82 is disposed along a second edge of the first section 72 of the blanket of coils. In one embodiment, the fastener 82 may be a hook and loop VELCRO strip. Alternatively, the fastener 82 may include non-metallic, snap-on buttons.

In accordance with aspects of the present technique, the second section 84 of a blanket of coils is coupled to a second side 78 of the patient cradle 66. A blanket connector 88 is used to couple a first edge of the second section 84 of the blanket to the second side 78 of the patient cradle 66 via one or more system connectors that are disposed proximate the patient cradle 66. The second section 84 of the blanket is typically narrower than the first section 72 of the blanket. A fastener 86 is disposed along a second edge of the second section 84 of the blanket. The fastener 86 may be a hook and loop VELCRO strip and/or non-metallic, snap-on buttons. Once the patient 12 is disposed on the patient cradle 66, the first fastener 82 and the second fastener 86 are detachably fastened to one another to secure the first section 72 and the second section 84 of the blanket of coils around the patient 12. In the embodiment depicted in FIG. 3, the second section 84 of the blanket typically does not include any coils.

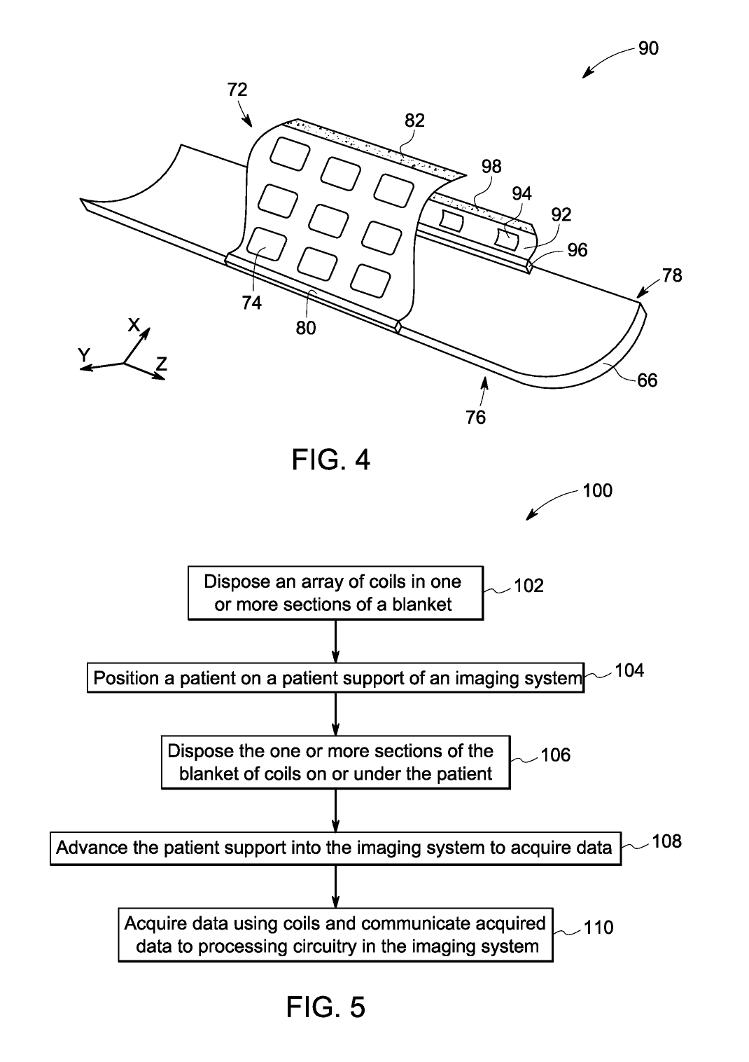

Referring now to FIG. 4, yet another embodiment 90 of the system 60 of FIG. 2 for communicating data is presented. The embodiment 90 depicted in FIG. 4 is substantially similar to the embodiment 70 of FIG. 3. Particularly, the system 90 includes a first section 72 and a second section 92 of the blanket of coils. More specifically, as depicted in FIG. 4, the narrower second section 84 of the blanket of FIG. 3 is replaced with a wider second section 92 of the blanket. In a presently contemplated configuration, the second section 92 also includes one or more rows of coils 94. This embodiment of the system 90 is configured to accommodate a larger patient. A blanket connector 96 is employed to detachably couple a first edge of the second section 92 of the blanket to the second side 78 of the patient cradle 66 via one or more system connectors that are disposed proximate the patient cradle 66. Furthermore, in certain embodiments, a fastener 98 is disposed along a second edge of the second section 92 of the blanket of coils. In one embodiment, the fastener 98 may be a hook and loop VELCRO strip and/or non-metallic snap-on buttons. The first fastener 82 associated with the first sections 72 of the blanket and the second fastener 98 are fastened to one another to secure the first section 72 and the second section 92 of the blanket of coils around the larger patient. Accordingly, the blanket of coils may be configured to accommodate a wide array of patient sizes.

With continuing reference to FIG. 4, the system includes coils 74 in the first section 72 of the blanket and coils 94 in the second section 92 of the blanket. In one embodiment, each coil 74 may overlap its nearest neighbors 74. In a similar fashion, each coil 94 may overlap its nearest neighbors 94. Accordingly, when the first section 72 of the blanket and the second section 92 of the blanket are fastened to one another, it is desirable that the subset of coils 74 closest to the fastener 82 overlaps with the subset of coils 94 closest to the fastener 98. In case of such an overlap between the subset of coils 74 and subset of coils 94, the fasteners 82 and 98 are positioned to insure proper overlaps between the subset of coils 74 in the first section 72 and the subset of coils 94 in the second section 92 of the blanket of coils. Here again, hook and loop VELCRO strips and/or non-metallic, snap-on buttons may be used as the fasteners 82, 98.

The embodiments of the blanket of coils 60, 70 and 90 presented in FIGS. 2-4 are representative of lightly tethered coils. Particularly, at least one side of the first and second sections of the blanket of coils are detachably coupled or tethered to the patient cradle 66, while the other sides of the first and second sections of the blanket of coils are operationally coupled to one another using the fasteners. Furthermore, it may be noted that in the systems 70 and 90 respectively depicted in FIG. 3 and FIG. 4, data signals acquired by the coils 74 and 94 may be processed by preamplifiers (not shown in FIGS. 3-4) and further transmitted to receivers (not shown in FIGS. 3-4) in the imaging system 10. It may further be noted that in certain embodiments, the systems 60, 70 and 90 may also include coils (not shown in FIGS. 2-4) embedded in the patient cradle 66.

FIG. 5 depicts a flowchart 100 illustrating an exemplary method for communicating data in an imaging system, in accordance with aspects of the present technique. The method starts at step 102, where a first array of coils is provided. In one embodiment, the coils are disposed on one or more sections of a flexible substrate patterned in the form of a blanket. By way of example, the coils 74 (see FIGS. 3-4) are disposed in the first section 72 of the blanket (see FIGS. 3-4). Additionally, the coils 94 (see FIG. 4) are also disposed in the second section 92 of the blanket (see FIG. 4).

Subsequently, as indicated by step 104, a patient, such as the patient 12 (see FIG. 2) is positioned on a patient support, such as the patient cradle 66 (see FIGS. 2-4) of the imaging system 10. Additionally, the one or more sections of the blanket of coils are draped over an anatomical region of the patient being imaged, as depicted by step 106. However, the one or more sections of the blanket may also be disposed under the patient. Furthermore, as previously noted, one end of each of the blanket sections is secured to one or more sides of the patient cradle, while the other ends of the blanket sections are fastened to one another over the patient. Moreover, at step 106 proper alignment of any overlapped coils is also ensured.

Furthermore, at step 108, the patient cradle is advanced into the imaging system and more particularly into the patient bore 20 (see FIG. 1) of the imaging system 10 (see FIG. 1) to acquire image data signals corresponding to the patient 12. Data corresponding to the patient are then acquired by the coils during a scanning procedure, as indicated by step 110. By way of example, during the scanning procedure, the patient cradle 66 having the patient 12 disposed thereon and the blanket of coils disposed over and/or under the patient 12 is advanced into the patient bore 20 (see FIG. 1). Also, at step 110, the acquired data are transmitted to processing circuitry in the imaging system. The acquired data are then processed and employed to generate an image of the anatomical region of the patient being scanned.

Furthermore, the foregoing examples, demonstrations, and process steps such as those that may be performed by the imaging system 10, may be implemented by suitable code on a processor-based system, such as a general-purpose or special-purpose computer. It should also be noted that different implementations of the present technique may perform some or all of the steps described herein in different orders or substantially concurrently, that is, in parallel. Furthermore, the functions may be implemented in a variety of programming languages, including but not limited to C++ or Java. Such code may be stored or adapted for storage on one or more tangible, machine readable media, such as on data repository chips, local or remote hard disks, optical disks (that is, CDs or DVDs), memory or other media, which may be accessed by a processor-based system to execute the stored code. Note that the tangible media may comprise paper or another suitable medium upon which the instructions are printed. For instance, the instructions may be electronically captured via optical scanning of the paper or other medium, then compiled, interpreted or otherwise processed in a suitable manner if necessary, and then stored in a data repository or memory.

The methods for communicating data and the various embodiments of the systems for communicating data described hereinabove dramatically enhance the performance of the imaging system. Particularly, use of blankets having coils disposed thereon for acquiring data and communicating the acquired data from the coils to processing circuitry in the patient cradle and the imaging system circumvents the need for external cabling, thereby enhancing patient comfort.

Furthermore, the lightweight lightly tethered coil arrays in the form of a blanket significantly increase patient comfort and scanner throughput. In addition, the need for bulky cable baluns used to block common-mode currents in cables is also minimized, thereby also reducing the significant amounts of heat dissipated by the bulky cable baluns.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A system for communicating data in a magnetic resonance imaging system, the system comprising:
a first array of receiver coils disposed on a first flexible substrate having at least one edge, wherein the flexible substrate is configured to be disposed upon or under a section of a patient under exam, wherein the first array of receiver coils is configured to acquire imaging data from the patient positioned on a patient support in the imaging system;
at least one blanket connector disposed along the at least one edge of the first flexible substrate, wherein the at least one blanket connector is electrically coupled to the first array of receiver coils in the first flexible substrate; and
at least one system connector disposed proximate the patient support and configured to communicate with the imaging system,
wherein the at least one blanket connector is configured to be detachably coupled to the at least one system connector, and wherein the first array of receiver coils is configured to communicate the acquired imaging data to the imaging system.

2. The system of claim 1, wherein the at least one blanket connector is further configured to physically secure the first array of receiver coils.

3. The system of claim 1, wherein the receiver coils are coupled to the at least one blanket connector through wiring that is internal to the first flexible substrate.

4. The system of claim 1, wherein the receiver coils in the first array of receiver coils are coupled to preamplifiers.

5. The system of claim 1, wherein the first flexible substrate is configured in various shapes and sizes, the shapes comprising a square shape, a rectangular shape, a circular shape, a polygonal shape, or combinations thereof.

6. The system of claim 1, wherein the first flexible substrate is configured as articles of clothing.

7. The system of claim 1, wherein the first flexible substrate comprises a fastener disposed on an edge of the first flexible substrate.

8. The system of claim 1, further comprising a second flexible substrate having a first edge coupled to one side of the patient support and a second edge, wherein the second flexible substrate is detachably fastened to the first flexible substrate.

9. The system of claim 8, wherein the second flexible substrate comprises a fastener disposed along a second edge, wherein the fastener is configured to aid in fastening the second flexible substrate to the first flexible substrate.

10. The system of claim 8, wherein the second flexible substrate comprises one or more rows of receiver coils.

11. The system of claim 10, wherein the second flexible substrate is coupled to the first flexible substrate such that the coils in the second flexible substrate are properly aligned with the coils in the first flexible substrate when there is an overlap between the coils in the first flexible substrate and the coils in the second flexible substrate.

12. A system for communicating data in a magnetic resonance imaging system, the system comprising:
a first flexible substrate having at least one edge and configured to be disposed on or under a patient, wherein the first flexible substrate comprises a first array of receiver coils configured to acquire data from the patient positioned on a patient support in the imaging system;
a first blanket connector disposed along the at least one edge of the first flexible substrate, wherein the at least one blanket connector is electrically coupled to the coils in the first array of receiver coils, and wherein the at least one blanket connector is configured to be detachably coupled to one or more sides of the patient support;
a second flexible substrate having at least one edge and configured to be disposed on or under a patient; and
a second blanket connector disposed along the at least one edge of the second flexible substrate, wherein the second blanket connector is configured to be detachably coupled to one or more sides of the patient support.

13. The system of claim 12, further comprising a first fastener disposed on a second edge of the first flexible substrate.

14. The system of claim 13, wherein the first fastener comprises a hook and loop strip or non-metallic snap-on buttons.

15. The system of claim 13, further comprising a second fastener disposed on a second edge of the second flexible substrate and configured to aid in fastening the second flexible substrate to the first flexible substrate.

16. The system of claim 15, wherein the second fastener comprises a hook and loop strip or non-metallic snap-on buttons.

17. The system of claim 12, wherein second flexible substrate comprises one or more receiver coils.

18. The system of claim 16, wherein the second flexible substrate is coupled to the first flexible substrate such that the coils in the second flexible substrate are properly aligned with the coils in the first flexible substrate when there is an overlap between the coils in the first flexible substrate and the coils in the second flexible substrate.

19. A method for communicating signals in a magnetic resonance imaging system, the method comprising:
disposing an array of receiver coils on one or more sections of a flexible substrate, wherein the array of receiver coils is configured to acquire data from a patient positioned on a patient support in the imaging system;
disposing one or more sections of the flexible substrate about the patient; and
communicating patient data acquired by the array of receiver coils to processing circuitry in the magnetic resonance imaging system through at least one blanket connector that is electrically coupled to the array of receiver coils.

20. The method of claim 19, wherein disposing the one or more sections of the flexible substrate about the patient comprises fastening one section of the flexible substrate with another section of the flexible substrate.

21. The method of claim 20, wherein fastening one section of the flexible substrate with another section of the flexible substrate comprises aligning the receiver coils in the sections of the flexible substrate when there is an overlap between the coils in the sections of the flexible substrate.

22. A system for a magnetic resonance imaging, comprising:
an acquisition subsystem configured to acquire image data, wherein the acquisition subsystem comprises:
a subsystem for communicating data in the imaging system, the subsystem comprising:
an array of receiver coils disposed on a first flexible substrate having at least one edge, wherein the flexible substrate is configured to be disposed upon or under a section of a patient under exam, wherein the first array of receiver coils is configured to acquire imaging data from the patient positioned on a patient support in the imaging system;
at least one blanket connector disposed along the at least one edge of the first flexible substrate, wherein the at least one blanket connector is electrically coupled to the first array of receiver coils in the first flexible substrate;
at least one system connector disposed proximate the patient support and configured to communicate with the imaging system,
wherein the at least one blanket connector is configured to be detachably coupled to the at least one system connector, and wherein the first array of receiver coils is configured to communicate the acquired imaging data to the imaging system; and
a processing subsystem in operative association with the acquisition subsystem and configured to process the acquired image data.
